(19) United States
(12) Patent Application Publication
(10) Pub. No.: US 2024/0356107 A1
(43) Pub. Date: Oct. 24, 2024

(54) Cooling System for Electrochemical or Electrotechnical Components

(71) Applicant: Gentherm Präzision SE, Treuchtlingen (DE)

(72) Inventor: Erich Doerfler, Landsberg (DE)

(21) Appl. No.: 18/612,155

(22) Filed: Mar. 21, 2024

(30) Foreign Application Priority Data
Apr. 21, 2023 (DE) 10 2023 110 282.6

(51) Int. Cl. H01M 10/6568; H01M 10/613; H01M 10/625; H05K 7/20

(52) U.S. Cl. CPC H01M 10/6568; H01M 10/613; H05K 7/20327; H01M 10/625; H01M 2220/20

(57) ABSTRACT

A cooling system that includes: a cooling device for two-phase cooling of electrical or electronic components, having a component housing for receiving the electrical or electronic components, having one inlet and one outlet for a cooling fluid; a compressor; a condenser; and a pump; the pump is inserted upstream of the inlet of the cooling device; the compressor is inserted downstream of the outlet of the cooling device and upstream of the condenser; the condenser is inserted upstream of the pump, so that a cooling circuit is formed; the cooling system has a liquid separator that is inserted between the outlet of the cooling device and the compressor to remove the liquid phase portion from the cooling fluid leaving the cooling device.

### CROSS-REFERENCE TO RELATED APPLICATIONS

This application claims the benefit of DE 10 2023 110 282.6, filed on Apr. 21, 2023, the entirety of which is hereby incorporated by reference herein for all purposes.

### FIELD

The application relates to a system for cooling electrochemical or electrotechnical components, and more particularly to a cooling system for battery cells in movable devices such as, for example, vehicles.

### BACKGROUND

A system for battery cooling is known from EP 3 113 279 A1, for example. A two-phase fluid is used in the known battery system. The gaseous coolant is either condensed in an upper-most module of a plurality of modules, or is conducted to a condenser via a gas line. The document relates in particular to a pump-free cooling system.

A pumped two-phase cooling system is known, for example, from US patent applications US 2018/0088607 A1 and US 2020/0166975 A1. The known two-phase cooling system comprises a micro-evaporator that is connected downstream to a condenser. The condenser is then connected downstream to a pump via a liquid reservoir. The pump is connected downstream to the microcondenser in the cooling circuit. The liquid reservoir dampens the oscillation of the flow. The known system does not have a compressor.

However, there is a need to provide cooling systems, in particular for larger battery and accumulator arrangements, that keep the aforesaid arrangements in a prespecified temperature range.

### SUMMARY

The cooling system according to these teachings comprises:
a cooling device for two-phase cooling of electrical or electronic components, comprising a component housing suitable for receiving the electrical or electronic components, having one inlet and one outlet for a cooling fluid,
a compressor,
a condenser, and
a pump,
   wherein the pump is inserted upstream of the inlet of the cooling device, wherein the compressor is inserted downstream of the outlet of the cooling device and upstream of the condenser,
   wherein furthermore the condenser is inserted upstream of the pump, so that a cooling circuit is formed,
   wherein the cooling system further comprises a liquid separator that is inserted between the outlet of the cooling device and the compressor in order to remove the liquid phase portion from the cooling fluid leaving the cooling device.

Usefully, a line is inserted between cooling device, i.e., its output, and the compressor and/or a line is inserted between compressor and condenser and/or a line is inserted between condenser and pump and/or a line is inserted between pump and cooling device, i.e., its inlet. The line may be a rigid line or a flexible hose.

According to the teachings herein, a cooling device shall be construed to be a device suitable for receiving one or a plurality of electronic or electrical components, e.g. batteries or accumulators, during the operation of which heat is generated, and for cooling this at least one electronic or electrical component.

The liquid separator has at least one inlet for the cooling fluid, which can have a gaseous and a liquid phase portion, e.g. in the form of small drops in a gaseous phase. The liquid separator itself has an outlet for the drier gas phase of the cooling fluid and a liquid outlet for the separated liquid portion of the cooling fluid.

The cooling fluid according to these teachings is designed such that, during operation of the at least one electronic or electrical component, the cooling fluid transitions to the gaseous state due to the heat. Usefully, the cooling fluid is liquid at room temperature. A phase transition temperature between liquid and gaseous phase can be selected to be, for example, 25° to 45°, in particular in the range of von 30° to 35°.

In the cooling system according to these teachings, entry of liquid phase portions into the compressor is reliably and effectively prevented by means of the liquid separator.

The liquid separator can be inserted upstream of the outlet of the cooling device, i.e., can be received in the component housing of the cooling device, or can be connected downstream thereof. In particular, the liquid separator can be arranged outside of the cooling device.

The cooling system usefully comprises a plurality of cooling devices that are connected to a common liquid separator. Using one common liquid separator can reduce the number of required liquid separators, which reduces the overall size of the system. Installation space is limited, in particular in cooling systems for vehicles, so that a small size makes sense. One liquid separator can be connected to a group of cooling devices of the plurality of cooling devices or can be connected to each of the cooling devices of the plurality of cooling devices. To this end, the outlets of the respective cooling devices are connected to the liquid separator in particular via lines. The outlets of a group of cooling devices or of the plurality of cooling devices can be combined via a coupling element to create a common outlet line that itself is connected to the liquid separator. The inlets of a group of cooling devices or of the plurality of cooling devices can be combined via a coupling element to create a common inlet line that itself is connected to the pump.

In one further embodiment, a liquid container is arranged between the condenser and the pump. The liquid container is usefully designed as a reservoir.

In one further embodiment, the cooling system further comprises a bypass that connects a liquid outlet of the liquid separator to a region of the cooling system downstream of the condenser. The bypass comprises a line.

In one embodiment, the bypass opens between condenser and pump, in particular into a liquid container arranged therebetween. In this embodiment, the liquid phase portion of the cooling fluid that has been separated in the liquid separator is conducted into the reservoir and can then be pumped, with the liquified portion of the cooling fluid present there, into the cooling device. In an alternative embodiment, the bypass opens directly into the pump. In a further alternative embodiment, the bypass opens between the pump and the inlet of the cooling device, or the inlets of the cooling devices, and can thus be conducted directly into the cooling device(s) again. In this embodiment, the bypass or the liquid separator is usefully secured against the cooling fluid flowing back into the liquid separator, in particular by means of a non-return valve, during pumping, and the pump is designed such that the cooling fluid can flow towards the inlet of the cooling device or the inlets of the cooling devices at prespecified intervals without counterpressure.

The liquid separator can be a cyclone liquid separator or a cold trap, for example.

In one embodiment, the liquid outlet of the liquid separator is provided with a flap or non-return valve. The flap or the non-return valve prevents liquid from being pressed back into the liquid separator.

In one embodiment, the liquid separator has a housing, an inlet, an outlet, and a liquid outlet arranged separated therefrom, wherein in particular one inlet is arranged tangential to a wall of the housing or in the housing, so that the fluid is caused to move in a spiral, wherein the liquid outlet is arranged on a bottom wall of the housing. When functional, the bottom wall is arranged at the bottom in the direction of gravity so that the liquid can drain off.

In embodiment the component housing of the cooling device is designed for receiving battery elements or accumulator elements.

Usefully, the component housing can have a controlled valve at the inlet.

The cooling system can in particular be designed as a cooling system for vehicle batteries, in particular for electric vehicle batteries.

### BRIEF DESCRIPTION OF THE DRAWINGS

This disclosure shall be described in greater detail in the following, also with respect to further features and advantages, using the description of exemplary embodiments and with reference to the enclosed drawings. Shown in the following schematic diagrams:

FIG. 1a: Schematic elevation of a cooling system of a first embodiment;

FIG. 1b: Schematic elevation of a cooling system of a second embodiment;

FIG. 2: Schematic elevation of a cooling system of a third embodiment;

FIG. 3: Schematic elevation of a cooling system of a fourth embodiment;

FIG. 4a: liquid separator;

FIG. 4b: horizontal section through the Liquid separator; and

FIG. 5: Cooling device.

### DETAILED DESCRIPTION

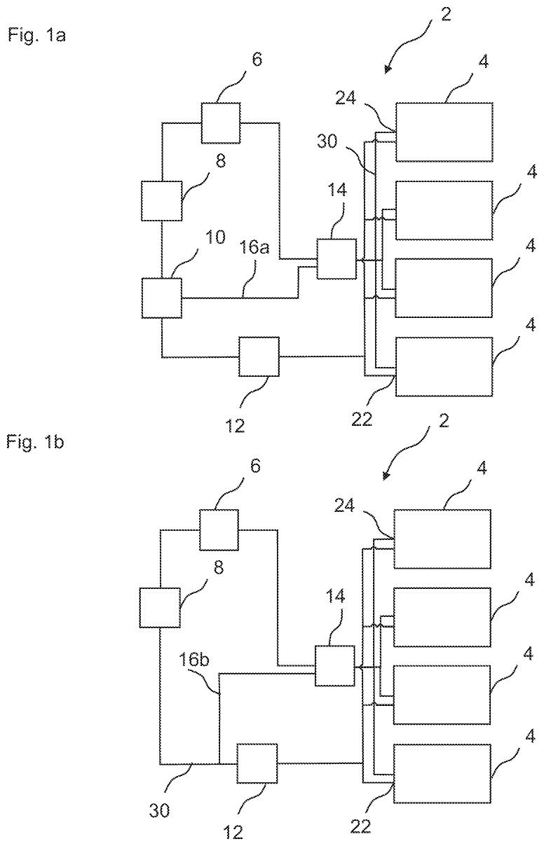

FIG. 1a is a schematic depiction of a cooling system 2 of a first embodiment. In this embodiment, the cooling system 2 comprises a plurality of cooling devices 4. The outlets of the cooling devices 4 are fluid-connected to a compressor 6. In particular gaseous cooling fluid is conducted through the outlets of the cooling devices 4 to the compressor 6. The cooling fluid is compressed in the compressor 6. The compressor 6 is fluid-connected to a condenser 8 downstream. The cooling fluid is conducted further from the compressor 6 to the condenser 8, in which the cooling fluid is liquified. A liquid container 10 can now be inserted downstream of the condenser 8, as shown.

Arranged in the cooling system 2 downstream of the condenser 8 and an optional liquid container 10 is a pump 12 that supplies the liquid cooling fluid to the cooling devices 4 again. The cooling devices 4 cool an object, in particular an electrical or electronic component, e.g. a battery element or an accumulator element. As shown schematically in FIG. 5, each of the cooling devices comprises a component housing 20, suitable for receiving the electrical or electronic components, having an inlet 22 and an outlet 24 for a cooling fluid. The inlet 22 can be provided with a valve 26.

In order to prevent liquid cooling fluid from travelling into the compressor 6, a liquid separator 14 is inserted between the outlet 24 of the cooling device 4 and the compressor 6. In the design shown, lines 30 exiting from the outlets 24 of the cooling devices 4 are first combined and then are connected to the inlet of the liquid separator 14. A liquid phase portion of the cooling fluid is separated from the gas phase portion of the cooling fluid in the liquid separator 14. The gas phase portion is conducted further to the compressor 6, while the liquid phase portion bypasses the compressor 6 and is supplied back to the cooling circuit of the cooling system downstream of the condenser 8. FIG. 1a illustrates that a bypass 16a introduces the liquid phase portion into a liquid container 10. FIG. 1b illustrates an alternative second design without the liquid container 10 in which a bypass 16b opens into the line 30, e.g. by means of a T-piece, between the condenser 8 and the pump 12.

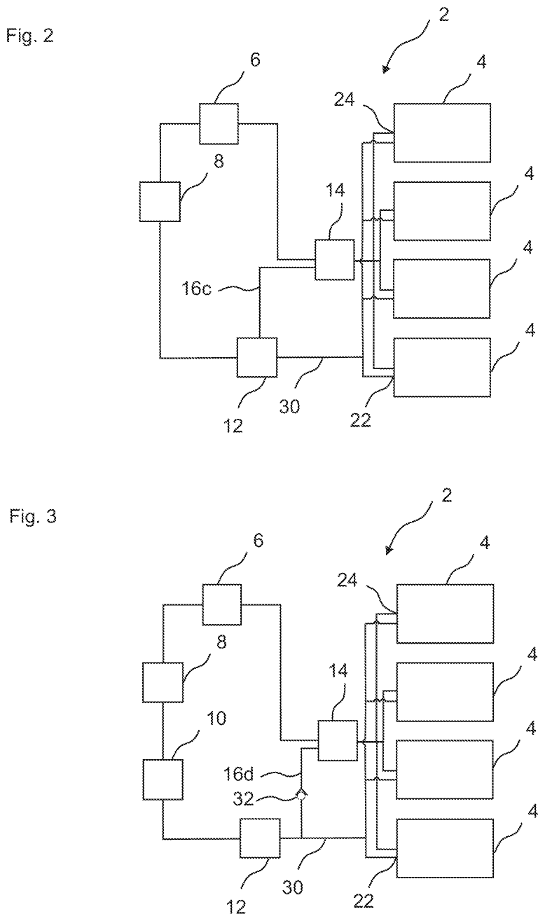

FIG. 2 illustrates a further design which in this case is depicted without a liquid container 10, but into which it is also possible to integrate a liquid container 10 as depicted in FIG. 1a. In this design, the pump 12 has a further inlet into which a bypass 16c opens. Liquid, i.e., the liquid phase part of the cooling fluid, can be intentionally suctioned out of the liquid separator 14 in such an embodiment.

FIG. 3 illustrates a further alternative design of the cooling system 2. In this design, the bypass 16d runs from the liquid separator 14 to a T-piece of the lines 30 downstream of the pump 12. In this embodiment, the pump 12 usefully applies pressure to the line(s) 30 between the pump 12 and the at least one cooling device 4 only at pre-specified time intervals so that liquid can flow out of the liquid separator 14 into the line 30 between the pump 12 and the at least one cooling device 4 into the latter at intervals with low pressure. The liquid separator 14 or the bypass 16d usefully has a non-return valve 32 in order to prevent liquid from being pressed back into the liquid separator 14 in an unintended manner.

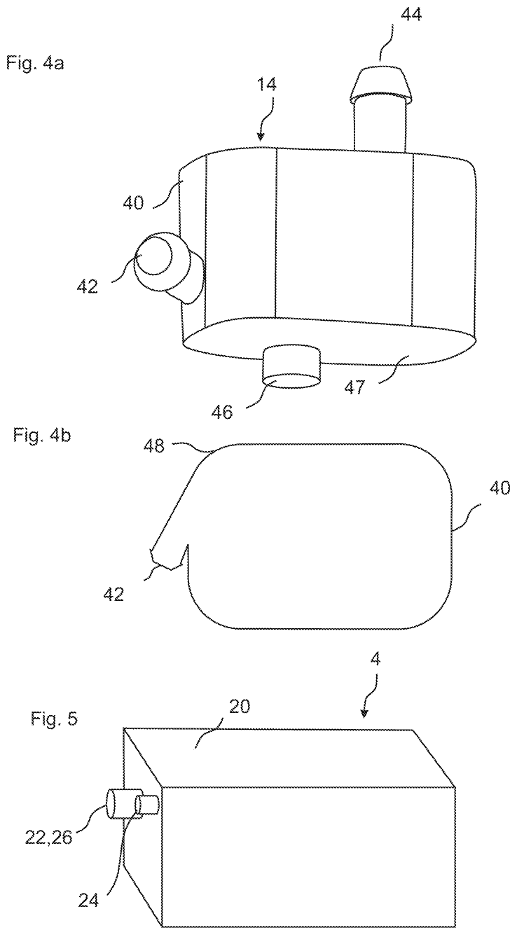

FIGS. 4a, b illustrate one design of a liquid separator 14. The liquid separator 14 comprises a housing 40 and an inlet 42. The outlet 44 for the gaseous portion of the cooling fluid is arranged on an upper wall of the housing, and the liquid outlet 46 is arranged on a lower wall or bottom wall 47 of the housing 40. Upper and lower refer to a downward gravitational force direction.

FIG. 4b illustrates a horizontal section through the liquid separator 14 in FIG. 4a at the height of the inlet 42. The inlet 42 is arranged tangential to a curved outer wall 48 of the housing 40, wherein this outer wall 48 is a wall oriented perpendicular to the bottom wall 47. A fluid flow that enters the housing 40 of the liquid separator 14 is caused to make a rotational movement, so that the two phases of the cooling fluid are separated by the different effect of centrifugal force and the liquid phase sinks to the bottom. The bottom can form a depression that slopes down to the liquid outlet 46. The liquid outlet 46 is provided in particular with a non-return valve, not shown, so that no liquid can press back into the liquid separator 14 and in particular flooding of the liquid separator 14 is prevented.

### REFERENCE LIST

2 Cooling system
4 Cooling device
6 Compressor
8 Condenser
10 Liquid container
12 Pump
14 Liquid separator
16a, 16b Bypass
20 Component housing
22 Inlet
24 Outlet
26 Valve
30 Line
32 Non-return valve
40 Housing
42 Inlet
44 Outlet
46 Liquid outlet
47 Bottom wall
48 Outer wall

1. A cooling system comprising:
a cooling device for two-phase cooling of electrical or electronic components, comprising a component housing suitable for receiving the electrical or electronic components, having one inlet and one outlet for a cooling fluid;
a compressor;
a condenser; and
a pump;
wherein the pump is inserted upstream of the inlet of the cooling device;
wherein the compressor is inserted downstream of the outlet of the cooling device and upstream of the condenser;
wherein the condenser is inserted upstream of the pump, so that a cooling circuit is formed;
wherein the cooling system comprises a liquid separator that is inserted between the outlet of the cooling device and the compressor to remove the liquid phase portion from the cooling fluid leaving the cooling device.

2. The cooling system according to claim 1, wherein the cooling system comprises a plurality of cooling devices that are connected to a common liquid separator.

3. The cooling system according to claim 1, wherein a liquid container is arranged between the condenser and the pump.

4. The cooling system according to claim 1, wherein the cooling system comprises a bypass that connects a liquid outlet of the liquid separator to a region of the cooling system downstream of the condenser.

5. The cooling system according to claim 4, wherein
a) the bypass opens between the condenser and the pump into a liquid container arranged therebetween, or,
b) the bypass opens into the pump, or,
c) the bypass opens between the pump and the inlet of the cooling device, and the liquid outlet or the bypass is provided with a non-return valve.

6. The cooling system according to claim 1, wherein the liquid separator is a cyclone liquid separator or a cold trap.

7. The cooling system according to claim 1, wherein a liquid outlet of the liquid separator is provided with a flap or non-return valve.

8. The cooling system according to claim 1, wherein the liquid separator has a housing, an inlet, an outlet, and a liquid outlet arranged separated therefrom;
wherein one inlet is arranged tangential to a wall of the housing or in the housing so that the fluid is caused to move in a spiral, and wherein the liquid outlet is arranged at a bottom wall of the housing.

9. The cooling system according to claim 1, wherein the component housing is configured for receiving battery elements or accumulator elements.

10. The cooling system according to claim 1, wherein the component housing has a controlled valve on the inlet.

11. A cooling system comprising:
a cooling device for two-phase cooling of electrical or electronic components, comprising a component housing suitable for receiving the electrical or electronic components, having one inlet and one outlet for a cooling fluid;
a compressor;
a condenser; and
a pump;
wherein the pump is inserted upstream of the inlet of the cooling device;
wherein the compressor is inserted downstream of the outlet of the cooling device and upstream of the condenser;
wherein the condenser is inserted upstream of the pump, so that a cooling circuit is formed;
wherein the cooling system comprises a liquid separator that is inserted between the outlet of the cooling device and the compressor to remove the liquid phase portion from the cooling fluid leaving the cooling device;
wherein the cooling system comprises a plurality of cooling devices that are connected to a common liquid separator;
wherein a liquid container is arranged between the condenser and the pump;
wherein the cooling system comprises a bypass that connects a liquid outlet of the liquid separator to a region of the cooling system downstream of the condenser;
wherein the liquid separator is a cyclone liquid separator or a cold trap;
wherein a liquid outlet of the liquid separator is provided with a flap or non-return valve;
wherein the liquid separator has a housing, an inlet, an outlet, and a liquid outlet arranged separated therefrom;
wherein one inlet is arranged tangential to a wall of the housing or in the housing so that the fluid is caused to move in a spiral, and wherein the liquid outlet is arranged at a bottom wall of the housing;
wherein the component housing is configured for receiving battery elements or accumulator elements; and
wherein the component housing has a controlled valve on the inlet.
